(19) United States
(12) Patent Application Publication
(10) Pub. No.: US 2012/0018770 A1
(43) Pub. Date: Jan. 26, 2012

(54) OLED LIGHT SOURCE HAVING IMPROVED TOTAL LIGHT EMISSION

(76) Inventors: Min-Hao Michael Lu, Castro Valley, CA (US); Peter Y.Y. Ngai, Alamo, CA (US)

(21) Appl. No.: 13/190,236

(22) Filed: Jul. 25, 2011

Related U.S. Application Data
(60) Provisional application No. 61/367,047, filed on Jul. 23, 2010.

(51) Int. Cl. H01L 33/62

(52) U.S. Cl. 257/99; 257/E33.064

(57) ABSTRACT

An OLED light source has a reduced area metal cathode such as a fine mesh cathode and a highly conductive electron conduction layer adjacent the cathode that allows for rapid lateral conduction of electrical current beneath the cathode to cause exciton formation over substantially the entire light emitting area of the OLED. By substantially reducing the coverage area of the cathode, cathode-exciton energy transfer (cathode quenching) produced by the presence of a metal cathode can be substantially reduced, and total light output from the OLED increased.

### CROSS-REFERENCE TO RELATED APPLICATIONS

This application claims the benefit of U.S. Provisional Patent Application No. 61/367,047 filed Jul. 23, 2010, which is incorporated herein by reference.

### FIELD OF THE INVENTION

The present invention generally relates to organic light emitting diodes (OLEDs) and more particularly to improvements in total light emission from a bottom-emitting OLED panel. The invention has particular application where OLED panels are used as light sources for general lighting, and where a relatively high lumen output is necessary to illuminate a space. However, the improvements of the invention will have general application in increasing the efficiency of an OLED. The present invention provides a bottom-emitting OLED that reduces the exciton-metal energy transfer (cathode quenching) that occurs near the cathode of the OLED and that increases the total lumen output of the OLED.

### SUMMARY OF THE INVENTION

The invention is directed to an OLED light source having a reduced area metal cathode and a highly conductive electron conduction layer adjacent the cathode that allows for rapid lateral conduction of electrical current within the electron transport layer to cause exciton formation over substantially the entire light emitting area of the OLED. By substantially reducing the coverage area of the cathode, cathode-exciton energy transfer produced by the presence of a metal cathode can be substantially reduced, thereby substantially reducing the degradation in the light output of the OLED caused by this energy transfer phenomenon.

### DESCRIPTION OF THE DRAWINGS

FIG. 1 is a pictorial illustration of a conventional OLED.

FIG. 2 is another pictorial illustration therefor, showing a light emitting area of the OLED created and defined by an insulator frame laid over the OLED's perimeter edges.

FIG. 3 is a pictorial illustration of an OLED in accordance with the invention having a reduced area mesh cathode and a doped electron transport layer for enhancing lateral conduction of electrons within the electron transport area.

FIG. 3A is a pictorial illustration of an alternative embodiment of an OLED in accordance with the invention having a reduced area mesh cathode and a separate highly conductive later above the electron transport layer for enhancing lateral conduction of electrons.

FIG. 4 is a top plan pictorial view of the mesh cathode of the OLED shown in FIG. 3.

FIGS. 5A-5B illustrate a two-shot masking process for producing the mesh cathode shown in FIG. 4.

FIG. 6 illustrates the increase in light emission from the OLED shown in FIG. 3.

FIG. 7 is a pictorial view of the OLED shown in FIGS. 3 and 6 illustrating an exemplary means of capturing additional realized light output from the OLED for use in down-light applications.

### DESCRIPTION OF THE ILLUSTRATED EMBODIMENT

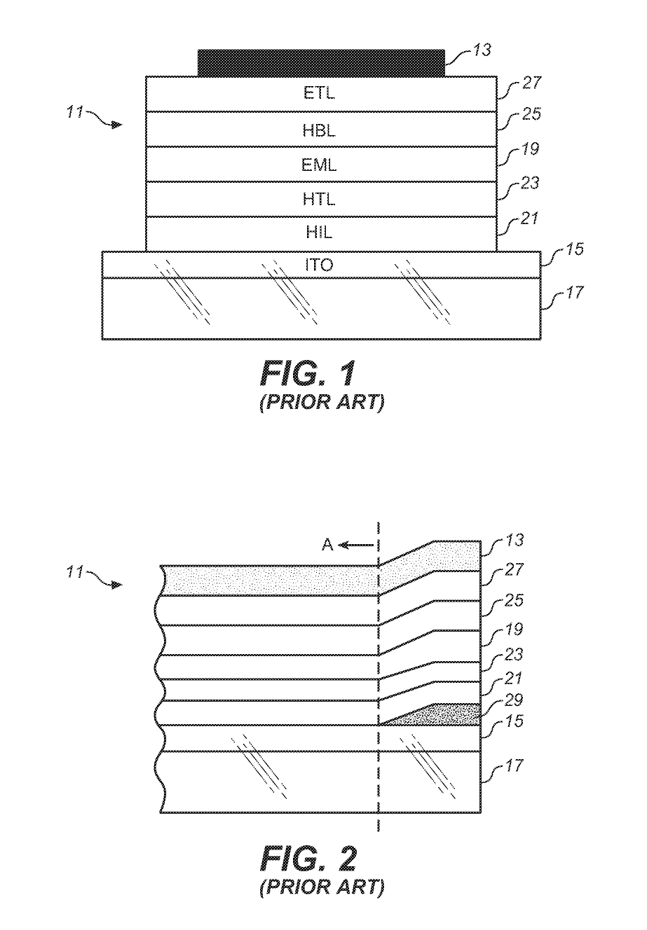

Referring now to the drawings, FIGS. 1 and 2 graphically illustrate a typical structure for a bottom-emitting OLED, generally denoted by the numeral 11, wherein thin layers of organic material are sandwiched between two thin electrodes. The electrodes consist of a metal, typically aluminum, cathode 13 at the top of the OLED and a transparent anode 15 at the bottom. The anode consists of a transparent conducting oxide, usually indium tin oxide (ITO), laid down over a transparent substrate 17, which is typically glass or clear plastic. The OLED is referred to as a “bottom-emitting OLED” because the light generated within the OLED is emitted through the bottom transparent anode and underlying transparent substrate. No light is emitted through the top of the OLED due to the presence of the cathode, which is opaque.

Light is generated within the OLED by a process that involves a recombination of holes and electrons produced when a current is applied across the OLED's electrodes 13, 15, (The holes are injected on the anode side of the OLED and electrons on the cathode side.) The recombination forms excitons that produce light as they decay, and mostly occurs within an OLED's light emitting layer (EML), denoted by the numeral 19. The holes and electrons are transported to the light emitting layer through the other layers of the OLED. On the anode side, these layers include a hole injection layer (HIL) 21 and a hole transport layer (HTL) 23; on the cathode side, they include a cathode-adjacent electron transport layer (ETL) 27, and a hole blocking layer (HBL) 25 that prevents hole injection into the electron transport layer. (The HBL is provided because holes have greater mobility than electrons and because hole injection into the ETL will degrade exciton formation in the EML.) A very thin electron injection layer (not shown) is also commonly provided between the cathode and the electron transport layer. In some OLEDs, part or all of the electron transport layer is doped with a conductivity dopant and the electron injection layer omitted. The doped electron transport lay ensures good electrical contact with the cathode.

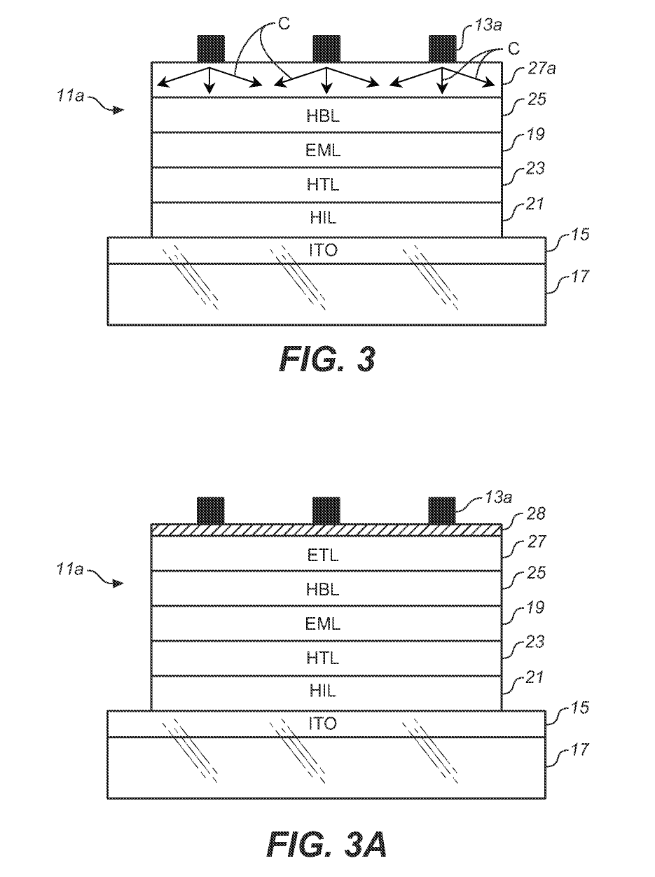

The organic layers of the OLED are typically deposited by vacuum thermal evaporation or solution processes such as spin-coating, inkjet printing or slot coating. In a multilayer deposition sequence, it is critical that deposition of subsequent layers does not damage or otherwise compromise the integrity of the underlying layers in order for the OLED to function properly. Techniques such as physical or plasma enhanced sputtering are known to generate energetic particles that can damage the underlying organic layers. Since transparent conducting oxides such as ITO are typically deposited by sputtering, they are not appropriate choices for layers of the OLED that overlay organic layers. This would include the cathode-adjacent high conductivity organic layer 27a or cathode-adjacent high conductivity inorganic layer 28 shown in FIGS. 3 and 3A, which are layers provided in the OLED in accordance with the invention as later described.

It should be noted that the structure of the OLED illustrated in the drawings is exemplary and that the invention can be implemented using other OLED structures. In particular, one or more light emitting layers or one light emitting layer containing multiple emitting dopants could be added to achieve a desired color output. (A single EML with a single dopant will likely result in a monochrome light source.) For example, three EMLs can be used to produce white light, which can be more readily adapted to general lighting applications.

The opaque metal cathode of the bottom emitting OLED will commonly cover the OLED's entire light emitting area. As shown in FIG. 2, the light emitting area (denoted by the letter A in FIG. 2) is created and defined by a framing insulator 29 placed over the edges of the ITO layer. As graphically depicted in FIG. 2, the subsequent layers of the OLED, including the cathode, slightly overhang the insulator frame to ensure that the light emitting area is completely covered.

The difficulty with the above-described configuration is that the close proximity of the cathode to the organic electroluminescent layers of the OLED compromises the ability of the OLED to operate at optimum efficiency. Energy from exciton decay can be lost to the metal cathode covering the electron transport layer metal-exciton energy transfer phenomenon sometimes referred to as cathode quenching or cathode energy transfer. Exciton formation occurs on the dopant organic molecules, and as they decay they emit a photon of a color determined by the HOMO-LUMO gap of the dopant molecule. (HOMO is the highest occupied molecular orbital; LUMO is the lowest unoccupied molecular orbital.) However, a visible photon is not produced when the metal-exciton energy transfer occurs. Instead, when an exciton is placed near metal, it can decay by transferring its energy radiatively to the metal. This metal-exciton energy transfer can account for 40% or more of the radiative decay of the exciton and is a significant impediment to increasing OLED efficiency.

FIG. 3 illustrates a bottom emission OLED in accordance with the invention which minimizes the efficiency suppressing effects of the OLED's cathode, and which thereby increases the number of lumens per watt that can be produced by the OLED. In this pictorially illustrated embodiment of the invention, the OLED 11a has an ITO layer 15 (anode), hole injection layer 21, hole transport layer 23, light emitting layer 19 and hole blocking layer laid down over a transparent substrate 17, as in the prior art versions of the OLED 11 illustrated in FIGS. 1 and 2. However, in this case the cathode 13a is provided in the form of a reduced area cathode, which does not cover the entirety of the light emitting area of the cathode. By reducing the coverage area of the cathode, metal-exciton energy transfer produced by the OLEO can be substantially reduced.

Area reduction in the OLED's cathode is achieved by providing a plurality of distributed openings 31 in the cathode over the OLED's light emitting area. By providing these distributed openings, only the portions of the organic material layer closest the cathode (the ETL) are covered by the metal cathode. As further described below, light that might otherwise be lost to metal-exciton energy transfer can be emitted through the distributed openings of the cathode, that is, through the top of the OLED, resulting in an increase in the total light emission from the OLEO.

However, light emission will not increase unless electrons can be injected into the areas of light emitting layer 19 where there is no coverage from the metal cathode 13a. To overcome this problem, a high-conductivity electron conduction layer is provided adjacent to the cathode to permit rapid lateral conduction of electrons beneath the cathode. In FIG. 3, this highly conductive layer is provided within the top organic electron transport layer 27a (ETL) of the OLED, where the rapid lateral conduction of electrons within the ETL is indicated by conduction arrows C. A high-conductivity ETL can be provided by doping the ETL with a suitable metal or organic dopant, such as lithium, cesium or certain organic n-type dopants. The lateral conduction of electrons within the ETL will cause exciton formation over substantially the entire light emitting area of the OLED; thus light can be produced from areas of the OLED not covered by the reduced area cathode.

FIG. 3A illustrates an alternative approach for achieving the lateral conduction of electrons below the reduced area cathode. As graphically represented in FIG. 3A, a separate, cathode-adjacent, inorganic, high-conductivity electron conduction layer 28 is provided above the organic electron transport layer 27 of the OLED. This inorganic, high-conductivity electron conduction layer can be a very thin layer of highly conductive material, such as a monolayer of graphene or a thermally-evaporated silicon monoxide, molybdenum oxide, or vanadium oxide having, for example, a one to two nanometer thickness. Generally, it is contemplated that an inorganic, high-conductivity electron conduction layer 28 will have a thickness of less than 5 nm to 10 nm.

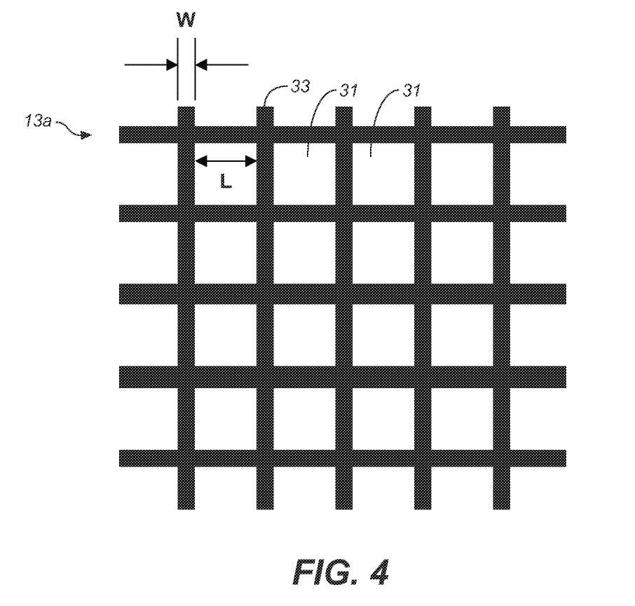

As shown in FIG. 4, the reduced area cathode 27a is suitably provided in the form of a fine, cross-mesh cathode, which provides for uniformly distributed openings over the OLED's light emitting area. The illustrated fine mesh cathode can suitably have the following characteristics to provide suitable coverage ratios for the cathode:
W≦100 μm and preferably ≦50 μm, where W is the width of the cathode mesh lines 33.
L≧100 μm and preferably ≧200 μm, where L is the width of the square openings 31 between cathode mesh lines.
ρ≦ohms-cm and preferably less than 10 ohms-cm, where ρ is the resistivity of the ETL.

The degree of coverage by the cathode its coverage ratio (R), can be determined by the following equation:

R=1−L²/(L+W)

Thus, for the fine mesh shown in FIG. 4 and described above, the coverage ratio suitably can be about 0.75 or less, and preferably can be about 0.36 or less. It will be understood that distributed openings can be provided in the cathode other than by the fine mesh structure illustrated in FIG. 4. For example, the cathode could be provided with a plurality of circular openings or openings of other shapes, preferably in a high enough density to achieve a coverage ratio that will result in a significant reduction in cathode quenching; for example, coverage ratios less than about 0.75, and preferably less than about 0.36. The distribution of the openings would preferably be uniform throughout the area of the cathode where the openings are provided, however, the invention is not intended to be limited to uniformly distributed openings.

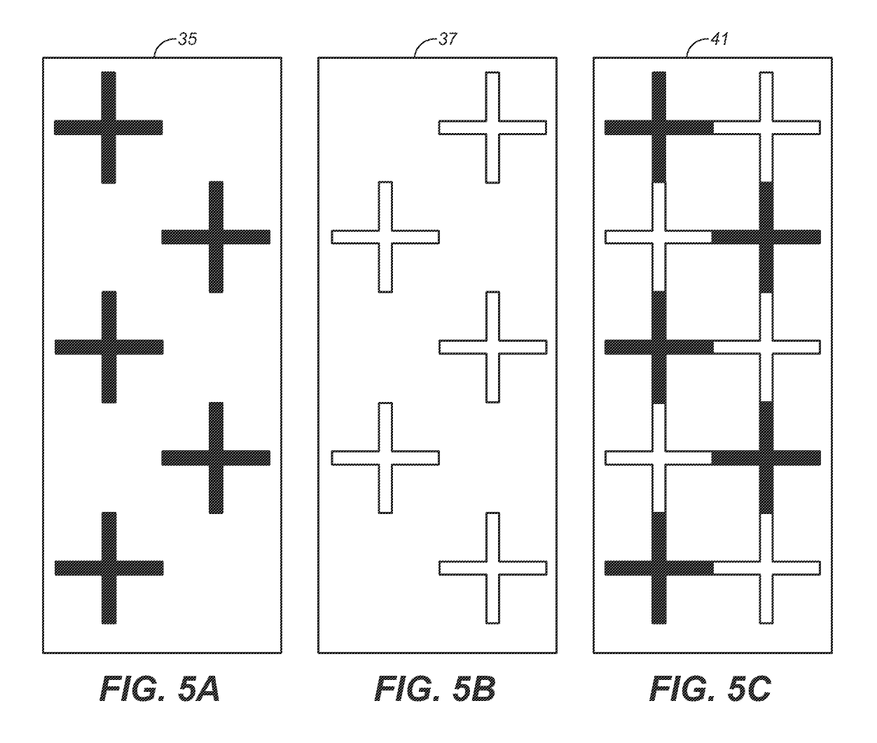

The mesh cathode shown in FIG. 4 can be applied to the OLED by a 2-shot shadow masking process as illustrated in FIGS. 5A-5B. In a 2-shot process, half the mesh structure is deposited on the underlying layer of the OLED (the doped organic ETL 27a in the case of the FIG. 3 embodiment, and the high-conductivity inorganic layer 28 in the case of the FIG. 3A embodiment) through a first shadow-mask 35 and the other half through a second shadow mask 37. The second shadow mask 37 can be an actual mask with off-set patterns or the first shadow mask, mechanically off-set.

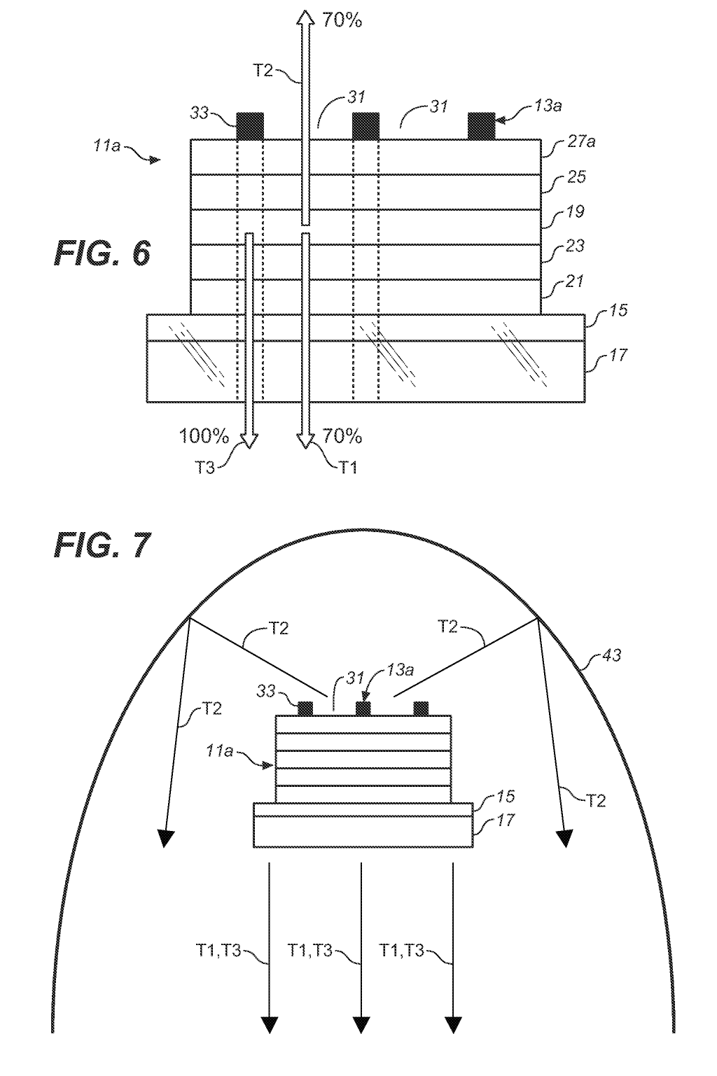

FIG. 6 pictorially illustrates how the gain in OLED light output is achieved using a reduced area fine mesh cathode as above-described. Substantially all of this gain occurs beneath the openings 31 in the mesh cathode 13a, where losses due to metal-excitons energy transfer do not occur. Assuming a gain of 40% in light output within these open regions, the light output from the OLED in these regions over the light output from the same regions of the conventional OLED shown in FIGS. 1 and 2 would be 140% of the conventional OLED. The OLED 11a of FIG. 3 would act as a bottom emitting OLED for about half of this gained light output, as represented by the 70% down arrow T1 in FIG. 6, and as a top emitting OLED for the other half of the gain, as represented by the 70% up arrow T2. Beneath the mesh lines of the cathode, there would be little or no gain in light output, and the OLED would act as a bottom emitting OLED as to substantially all of this locally generated light, as represented by the 100% down arrow T3.

FIG. 7 shows an example of how the additional realized light output emerging from the top of the OLED as shown in FIG. 6 can be captured for use in a down-light application, such as a down-light only luminaire. Here, the OLED 11 having a mesh metal cathode 13a with mesh openings 31 produces top emitted light (“up-light”) represented by light ray arrows T2, as well as bottom emitted light (“down-light”) represented by light ray arrows T1. T3. T1 and T2 represent the realized light from the areas of the OLED beneath the cathode's open areas 31, and T3 represents the realized light from the areas of the OLED beneath the cathode lines 31. In FIG. 7, a parabolic reflector, suitably a specular reflector, is positioned over the OLED source 11 so as to redirect the up-light T2 in a downward direction, whereby substantially all the light emitted from the OLED emerges from the OLED-reflector system as down-light. Similarly, a reflector, such as a suitably sized specular parabolic reflector, could be placed under OLED 11 for redirecting the down-light components T1, T3 of the OLED upwardly, so that substantially all the light emitted from the OLED emerges from the OLED-reflector system as up-light.

It will be appreciated that other light-control elements could be used in place of, or in combination with, a reflector to redirect light emitted by the OLED, including lenses, micro-lenses, and reflectors of different shapes positioned in close proximity to the OLED. It will also be appreciated that an OLED in accordance with the invention can be used to simultaneously produce both up-light and down-light for up/down light applications. Thus, OLEDs in accordance with the invention can be adapted to many different general lighting applications including direct lighting, indirect lighting and direct indirect lighting.

While the invention has been discussed in considerable detail in the foregoing specification and the accompanying drawings, it is not intended that the invention be limited to such detail except as may otherwise be expressly state herein or as necessitated by the following claims.

We claim:

1. An organic light emitting diode (OLED) having reduced cathode quenching and increased total light output, said OLED comprising
a cathode layer defining a top of the OLED,
a transparent anode layer defining a transparent bottom of the OLED through which light produced within the OLED is emitted,
organic material layers including at least one light emitting layer between said cathode layer and anode layer for producing light over a light emitting area of the OLED when a current is applied across the OLED between the cathode and anode layers,
said cathode layer having a plurality of openings, wherein portions of the organic material layers are covered by the cathode and portions are not covered by the cathode, resulting in reduced coverage of the light emitting area of the OLED and reduced cathode quenching, and
a cathode-adjacent, high-conductivity electron conduction layer for providing rapid lateral conduction of electrons beneath the cathode from covered portions of the OLED's light emitting area to uncovered portions of the OLED's light emitting area,
the plurality of openings in the cathode layer being provided such that light produced in the organic material layers of the OLED, including in the light emitting layer, can be emitted from the top of the OLED as well as from the transparent bottom of the OLED.

2. The OLED of claim 1 wherein said cathode is in the form of a mesh cathode having mesh openings and wherein the reduced coverage area of the cathode is determined by the size and density of the openings.

3. The OLED of claim 2 wherein the mesh cathode is formed by perpendicular crossing cathode mesh lines forming mesh openings.

4. The OLED of claim 2 wherein the mesh cathode is formed by perpendicular crossing cathode mesh lines forming square mesh openings.

5. The OLED of claim 3 wherein the width of said crossing cathode mesh lines is no greater than about 100 μm, and the width of said square mesh openings is greater than about 100 μm.

6. The OLED of claim 3 wherein the width of said crossing cathode mesh lines is no greater than about 50 μm, and the width of said square mesh openings is greater than about 200 μm.

7. The OLED of claim 1 wherein the reduced coverage area over the light emitting area of the OLED has a coverage ratio (R) of no greater than about 0.75.

8. The OLED of claim 1 wherein the reduced coverage area over the light emitting area of the OLED has a coverage ratio (R) of no greater than about 0.36.

9. The OLED of claim 1 wherein said cathode-adjacent, high-conductivity electron conduction layer has a resistivity (ρ) no greater than about 200 ohms-cm.

10. The OLED of claim 1 wherein said cathode-adjacent, high-conductivity electron conduction layer has a resistivity (ρ) no greater than about 10 ohms-cm.

11. The OLED of claim 1 wherein the organic material layers of the OLED include a cathode-adjacent electron transport layer, and wherein said electron transport layer is doped with a dopant for increasing the conductivity of such layer and wherein said doped electron transport layer acts as a cathode-adjacent, high-conductivity electron conduction layer of the OLED.

12. The OLED of claim 1 wherein the cathode-adjacent high-conductivity electron conduction layer of the OLED is a layer of highly conductive inorganic material between the reduced coverage cathode and the organic material layers of the OLED.

13. The OLED of claim 12 wherein said layer of highly conductive inorganic material includes a monolayer of graphene.

14. The OLED of claim 12 wherein said layer of highly conductive inorganic material includes a thermally evaporated layer of material selected from the group consisting of silicon monoxide, molybdenum oxide, and vanadium oxide.

15. An organic light emitting diode (OLED) having reduced cathode quenching and increased light output, said OLED comprising
a fine mesh cathode layer defining a top of the OLED, said mesh cathode have substantially uniform mesh openings formed by perpendicular crossing cathode mesh lines,
a bottom transparent anode layer defining a transparent bottom of the OLED through which light produced in the OLED can be emitted,
organic material layers including at least one light emitting layer and a cathode-adjacent electron transport layer between said cathode layer and anode layer for producing light over a light emitting area of the OLED when a current is applied across the OLED between the cathode and anode layers,
the electron transport layer of said organic material layers being doped with a dopant for increasing the conductivity of such layer for providing rapid lateral conduction of electrons beneath the cathode,
the mesh openings in the cathode layer providing a reduced area cathode for reduced cathode quenching and allowing light produced within the OLED to be emitted from the top of the OLED as well as from the transparent bottom of the OLED.

16. The OLED of claim 15 wherein the width of said crossing cathode mesh lines is no greater than about 100 μm, and the smallest dimension of said mesh openings is greater than about 100 μm.

17. The OLED of claim 15 wherein the width of said crossing cathode mesh lines is no greater than about 50 μm, and the smallest dimension of said mesh openings is greater than about 200 μm.

18. The OLED of claim 15 wherein said high-conductivity electron transport layer has a resistivity (ρ) no greater than about 200 ohms-cm.

19. The OLED of claim 15 wherein said high-conductivity electron transport layer has a resistivity (ρ) no greater than about 10 ohms-cm.

20. The OLED of claim 15 wherein said fine mesh cathode is applied to the electron transport layer by a 2-shot shadow masking process.

21. An organic light emitting diode (OLED) having reduced cathode quenching and increased light output, said OLED comprising
a mesh cathode layer defining a top of the OLED, said mesh cathode having substantially uniform mesh openings,
a bottom transparent anode layer defining a transparent bottom of the OLED through which fight produced in the OLED can be emitted,
organic material layers including at least one light emitting layer and a cathode-adjacent electron transport layer between said cathode layer and anode layer for producing light over a fight emitting area of the OLED when a current is applied across the OLED between the cathode and anode layers,
a cathode-adjacent layer of highly conductive inorganic material between the reduced coverage cathode and the organic material layers of the OLED for providing rapid lateral conduction of electrons beneath the cathode,
the mesh openings in the cathode layer providing a reduced area cathode for reduced cathode quenching and allowing fight produced within the OLED to be emitted from the top of the OLED as well as from the transparent bottom of the OLED.

22. The OLED of claim 21 wherein said layer of highly conductive inorganic material includes a monolayer of graphene.

23. The OLED of claim 21 wherein said layer of highly conductive inorganic material includes a thermally evaporated layer of material selected from the group consisting of silicon monoxide, molybdenum oxide, and vanadium oxide.

24. The OLED of claim 21 wherein said fine mesh cathode is applied to the layer of highly conductive inorganic material by a 2-shot shadow masking process.
